(19) United States
(12) Patent Application Publication
(10) Pub. No.: US 2023/0003809 A1
(43) Pub. Date: Jan. 5, 2023

(54) DETERIORATION ESTIMATION DEVICE, DETERIORATION ESTIMATION SYSTEM, DETERIORATION ESTIMATION METHOD, AND COMPUTER PROGRAM

(71) Applicant: GS YUASA INTERNATIONAL LTD., Kyoto-shi, Kyoto (JP)

(72) Inventor: Yasunori MIZOGUCHI, Kyoto-shi, Kyoto (JP)

(21) Appl. No.: 17/781,983

(22) PCT Filed: Dec. 4, 2020
(86) PCT No.: PCT/JP2020/045249

§ 371 Date: Jun. 2, 2022

(30) Foreign Application Priority Data
Dec. 6, 2019 (JP) 2019-221580

(51) Int. Cl. G01R 31/392; G01R 31/367; G01R 31/379; G01R 31/389; H02J 7/00; G01R 31/3842

(52) U.S. Cl. CPC G01R 31/392; G01R 31/367; G01R 31/379; G01R 31/389; H02J 7/0048; H02J 7/00712; G01R 31/3842

(57) ABSTRACT

A deterioration estimation device (1) includes: a discharge control unit (11) configured to discharge a lead-acid battery (3) or a lead-acid battery module (4) that includes a plurality of lead-acid batteries until the lead-acid battery (3) or the lead-acid battery module (4) reaches a predetermined SOC; and a first estimation unit (11) configured to estimate a rate of deterioration of the lead-acid battery (3) or the lead-acid battery module (4) based on internal resistance or conductance derived when the lead-acid battery (3) or the lead-acid battery module (4) is discharged.

### TECHNICAL FIELD

The present invention relates to a deterioration estimation device, a deterioration estimation system, a deterioration estimation method, and a computer program for estimating the deterioration of a lead-acid battery or a lead-acid battery module.

### BACKGROUND ART

Lead-acid batteries are used in various applications besides in-vehicle applications and applications for industry. For example, a secondary battery (energy storage device) such as an in-vehicle lead-acid battery is mounted on a moving body such as a vehicle. Here, the vehicle includes an automobile, a motorcycle, a forklift, or a golf car, for example. The secondary battery is used as a power supply source that supplies electricity to a starter motor at the time of starting an engine and a power supply source that supplies electricity to various electrical components such as lights.

Lead-acid batteries for industry are used as a power supply source to an emergency power supply or an uninterruptible power supply (UPS). In power storage systems and the like used for leveling power obtained by sunlight, wind power or the like, a large number of lead-acid batteries are connected in parallel and in series thus constructing a large-scale power storage system. To distinguish the lead-acid batteries for industry from in-vehicle lead-acid batteries, the lead-acid batteries for industry are sometimes referred to as stationary lead-acid batteries.

It has been known that the deterioration of a lead-acid battery progresses due to various factors. To prevent stopping of the supply of electricity caused by the occurrence of a state where a lead-acid battery unexpectedly loses its function, it is necessary to appropriately determine the rate of deterioration of the lead-acid battery, and to appropriately determine whether or not it is necessary to exchange the lead-acid battery.

In an electric power storage system or the like, there may arise a difference in the progress of deterioration between lead-acid batteries due to a temperature of a place where the lead-acid batteries are installed, irregularities in performance among the respective lead-acid batteries or the like. Therefore, each time the lead-acid batteries deteriorate, it is necessary to exchange some lead-acid batteries and hence, the maintenance of the lead-acid batteries has been cumbersome.

Conventionally, the determination of deterioration of a lead-acid battery has been performed mainly by using an internal resistance (a direct current or an alternating current) at the time of full charging. When the deterioration of the lead-acid battery occurs due to corrosion of a positive electrode current collector, a deterioration state can be diagnosed by using this method.

In a power supply control method described in Patent Document 1, an internal resistance of a lead-acid battery during charging and an internal resistance of the lead-acid battery during discharging are estimated, a first degree of deterioration of the lead-acid battery during charging is obtained from an initial value of an internal resistance during charging and an estimated internal resistance during charging, and a second degree of deterioration of the lead-acid battery during discharging is obtained from an initial value of the internal resistance during discharging, and an estimated internal resistance during discharging. A deterioration state of the lead-acid battery is determined based on the first degree of determination and the second degree of deterioration, and when the first degree of deterioration and the second degree of deterioration exceed a threshold, the lead-acid battery is exchanged

### PRIOR ART DOCUMENT

### Patent Documents

Patent Document 1: JP-A-2019-109237

### SUMMARY OF THE INVENTION

### Problems to be Solved by the Invention

In applications such as a power storage system where the number of times of charging and discharging is large, the deterioration of a positive electrode material called softening of a positive electrode progresses. In this deterioration mode, an internal resistance at the time of full charging hardly increases. Accordingly, it is difficult to diagnose a deterioration state of the lead-acid battery based on the internal resistance at the time of full charging.

According to a power supply control method described in Patent Document 1, it is possible to determine the deterioration with time such as depletion of electrolyte and corrosion of a positive electrode grid. However, it is not possible to estimate the rate of deterioration based on the above-described softening of the positive electrode. When the softening of the positive electrode progresses, a deterioration state of the lead-acid battery cannot be correctly estimated by a conventional diagnosis based on an internal resistance in a fully charged state. Accordingly, there is a concern that some lead-acid batteries that exceed a service limit are used in a connected state.

Accordingly, it is an object of the present invention to provide a deterioration estimation device, a deterioration estimation system, a deterioration estimation method, and a computer program for estimating the deterioration of a lead-acid battery or a lead-acid battery module caused by softening of a positive electrode.

### Means for Solving the Problems

According to an aspect of the present invention, there is provided a deterioration estimation device that includes: a discharge control unit configured to discharge a lead-acid battery or a lead-acid battery module that includes a plurality of lead-acid batteries until the lead-acid battery or the lead-acid battery module reaches a predetermined SOC; and a first estimation unit configured to estimate a rate of deterioration of the lead-acid battery or the lead-acid battery module based on internal resistance or conductance derived when the lead-acid battery or the lead-acid battery module is discharged.

According to an aspect of the present invention, there is provided a deterioration estimation system that includes: the above-described deterioration estimation device; and a terminal configured to transmit a current, a voltage, the internal resistance or the conductance to the deterioration estimation device, wherein the deterioration estimation device makes the terminal display a rate of deterioration estimated by the first estimation unit.

According to an aspect of the present invention, there is provided a deterioration estimation method that includes: deriving an internal resistance or conductance in a case where a lead-acid battery or a lead-acid battery module that includes a plurality of lead-acid batteries is discharged until the lead-acid battery or the lead-acid battery module reaches a predetermined SOC; and estimating a rate of deterioration of the lead-acid battery or the lead-acid battery module based on the derived internal resistance or conductance.

According to an aspect of the present invention, there is provided a computer program that allows a computer to execute processing that includes: deriving an internal resistance or conductance in a case where a lead-acid battery or a lead-acid battery module that includes a plurality of lead-acid batteries is discharged until the lead-acid battery or the lead-acid battery module reaches a predetermined SOC; and estimating a rate of deterioration of the lead-acid battery or the lead-acid battery module based on the derived internal resistance or conductance.

### BRIEF DESCRIPTION OF THE DRAWINGS

FIG. 1 is a block diagram illustrating an example of the configuration of a deterioration estimation system according to an embodiment 1.

FIG. 2 is a graph illustrating an example of a first degree-of-deterioration curve.

FIG. 3 is a flowchart illustrating steps of processing in which a control unit estimates a degree of deterioration of a battery, and adjusts a load of the battery.

FIG. 4 is a graph showing a result of examining internal resistances of respective batteries 1 to 6 whose capacities are lowered when the batteries 1 to 6 are deeply discharged until a state of charge (SOC) reaches 30%.

FIG. 5 is a graph showing a result of examining internal resistances of batteries 1 to 6 with lowered capacities in a fully charged state.

FIG. 6 is a flowchart illustrating steps of processing in which a control unit estimates the degree of deterioration of the battery, and estimates the transition of the degree of deterioration of the battery and a life of the battery.

FIG. 7 is an explanatory graph illustrating a method of estimating a second degree-of-deterioration curve.

FIG. 8 is a flowchart illustrating steps of processing in which a control unit estimates the transition of an internal resistance of the battery, and estimates the transition of the degree of deterioration and a life of the battery.

FIG. 9 is an explanatory graph illustrating a method of estimating an internal resistance curve.

FIG. 10 is a flowchart illustrating steps of processing in a case where refresh charging is simultaneously performed when the control unit performs discharging until the battery reaches a predetermined SOC.

FIG. 11 is a block diagram illustrating the configuration of a deterioration estimation system according to an embodiment 2.

FIG. 12 is a schematic view illustrating an example of a learning model.

FIG. 13 is a flowchart illustrating steps of processing for generating the learning model by the control unit.

FIG. 14 is a flowchart illustrating steps of processing in which the control unit estimates the rate of deterioration of the battery.

FIG. 15 is a schematic view illustrating an example of the learning model.

FIG. 16 is a flowchart illustrating steps of processing in which the control unit estimates the rate of deterioration of the battery.

FIG. 17 is an explanatory table relating to processing of generating a learning model according to an embodiment 4.

FIG. 18 is a flowchart illustrating steps of processing in which a control unit estimates the degree of deterioration of the battery, and estimates the transition of the degree of deterioration of the battery and a life of the battery.

FIG. 19 is an explanatory view illustrating the configuration of a learning model according to an embodiment 5.

FIG. 20 is a flowchart illustrating steps of processing in which a control unit derives an internal resistance of the battery, and estimates the transition of the degree of deterioration and a life of the battery.

FIG. 21 is an explanatory table relating to processing of generating a learning model according to an embodiment 6.

FIG. 22 is a flowchart illustrating steps of processing in which a control unit estimates an internal resistance of the battery, and estimates the transition of the degree of deterioration and a life of the battery.

### MODE FOR CARRYING OUT THE INVENTION

### Overall Configuration of Embodiments

A deterioration estimation device according to the embodiment includes: a discharge control unit configured to discharge a lead-acid battery or a lead-acid battery module that includes a plurality of lead-acid batteries until the lead-acid battery or the lead-acid battery module reaches a predetermined SOC; and

a first estimation unit configured to estimate a rate of deterioration of the lead-acid battery or the lead-acid battery module based on internal resistance or conductance derived when the lead-acid battery or the lead-acid battery module is discharged.

Here, SOC is a value that expresses a ratio of residual capacity Cᵣ with respect to a full charge capacity C_{full} by percentage, and is calculated by the following equation.

SOC=Cᵣ/C_{full}×100[%]

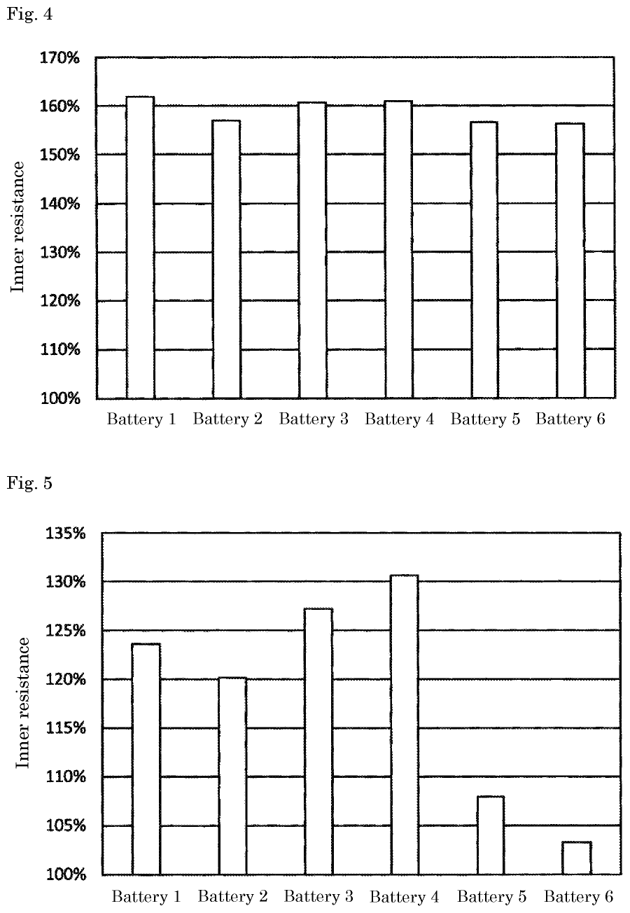

The inventors of the present invention have found that, even in a case where a lead-acid battery is used in an application where a life of the battery terminates due to softening of a positive electrode as in the case of a power storage system or the like, the rate of deterioration can be favorably estimated based on an internal resistance or conductance when deep discharging is performed, and have completed the present invention (see FIG. 4 and FIG. 5).

It is considered that when the softening of the positive electrode progresses, the bonding between active material particles that form a positive electrode material becomes weak and hence, the resistance of the positive electrode material increases. However, in a fully charged state, that is, when almost all active material is made of conductive PbO₂, an increase amount of the internal resistance is not large. Accordingly, a ratio of the internal resistance generated by the softening of the positive electrode with respect to the internal resistance of the entire battery is extremely small. At the end of the life of the battery, the internal resistance of the entire battery is determined based on a corrosion state of a positive electrode current collector, the depletion of an electrolyte or the like. However, in a case where the softening of the positive electrode progresses although the corrosion of the current collector is slight, for example, the remaining life of the battery cannot be accurately determined. When the battery is deeply discharged, insulating PbSO₄ is further generated at a position where the bonding between the active material particles in the positive electrode is weakened due to softening. Accordingly, the resistance of the positive electrode material remarkably increases. That is, in a deep discharge state, the internal resistance of the battery increases corresponding to the rate of progress of softening of the positive electrode. The increase in resistance caused by corrosion of the current collector or the like affects the internal resistance of the battery regardless of a discharge state.

According to the above-described configuration, it is possible to obtain information on a deterioration state of the lead-acid battery based on the internal resistance when deep discharge is performed in consideration of many deterioration modes such as the softening of the positive electrode, the corrosion of the current collector, and the depletion of electrolyte. Accordingly, it is possible to favorably estimate the rate of deterioration.

It is preferable that the predetermined SOC (the estimated SOC) fall within a range of 0% to 40%. When the ratio of SOC exceeds 40%, an amount of increase of internal resistance caused by softening of the positive electrode is small. Accordingly, the deterioration cannot be accurately detected. It is more preferable that SOC be 40%, and it is further more preferable that SOC be 30%.

The estimated SOC is derived as follows.

With respect to a battery having an actual capacity Q0 [Ah], an estimated SOCT1 obtained after an electric quantity Q1 [Ah] is discharged from SOC_{T0} at a certain point of time T0 is calculated by the following equation.

SOC_{T1}=SOC_{T0}−Q1/Q0[%]

The estimated SOC_{T2} after an electric quantity Q2 [Ah] is charged from the SOC_{T1} is calculated by the following equation.

SOC_{T2}=SOC_{T1}+Q2/Q0[%]=SOC_{T0}−Q1/Q0+Q2/Q0[%]

The deterioration estimation device may be a battery control device that controls charging and discharging of a lead-acid battery included in a power storage system or the like. Alternatively, the deterioration estimation device may control charging and discharging of the battery control device by a remote control.

In the deterioration estimation device described above, the internal resistance may be one or more selected from a group consisting of; a first internal resistance derived based on a current and a voltage immediately before the end of discharging and a current and a voltage immediately after the end of discharging; a second internal resistance derived based on a current and a voltage immediately before the start of charging and a current and a voltage immediately after the start of charging; and a third internal resistance derived from a response when an alternating current or an alternating voltage is applied to the lead-acid battery that has reached a predetermined SOC.

With such a configuration, the internal resistance can be accurately derived.

The first internal resistance R is derived from the following equation (1) in a case where the first internal resistance R is paused after discharging.

R=ΔV/ΔI=(V2−V1)/(I2−I1) equation (1)

In the equation (1), V1: voltage immediately before the end of discharging, I1: current immediately before end of discharging

V2: voltage immediately after end of discharging (at a point of time that a pause starts), I2: current immediately after end of discharging

The time immediately before discharging finishes means, for example, 0.1 seconds before a point of time that discharging finishes, 1 second before the point of time that discharging finishes, 5 seconds before the point of time that discharging finishes, or 10 seconds before the point of time that discharging finishes. On the other hand, the time immediately after the end of discharging means, for example, 0.1 seconds after a point of time that discharging finishes, 1 second after the point of time that discharging finishes, 5 seconds after the point of time that discharging ends, or 10 seconds after the point of time that discharging finishes.

The second internal resistance R is derived from the following equation (2) in a case where the battery is charged after a pause.

R=ΔV/ΔI=(V4−V3)/(I4−I3) equation (2)

In the equation (2), V3: voltage immediately before the start of charging (at a point of time a pause finishes), I3: current immediately before charging starts

V4: voltage immediately after charging starts, I4: current immediately after charging starts

In a case where charging is performed without a pause after discharging,

Immediately after end of discharging=at a point of time that charging starts

A point of time that discharging finishes=immediately before charging starts. Accordingly, the internal resistance is calculated by the same equation as the first internal resistance or the second internal resistance. That is, in this case, the internal resistance R is derived by the following equation (3).

R=ΔV/ΔI=(V2−V1)/(I2−I1) equation (3)

In the equation (3), V1: a point of time that discharging finishes (immediately before the start of charging), I1: current at a point of time that discharging finishes

V2: voltage immediately after end of discharging (at a point of time charging starts), I2: current immediately after the end of discharging

The time immediately before the start of charging means a point of time such as, for example, 0.1 seconds before a point of time that charging starts, 1 second before the point of time that charging starts, 5 seconds before the point of time that charging starts, or 10 seconds before the point of time that charging starts. The time immediately after the start of charging means a point of time such as, for example, 0.1 seconds after a point of time that charging starts, 1 second after the point of time that charging starts, 5 seconds after the point of time that charging starts, or 10 seconds after the point of time that charging starts.

The third internal resistance is calculated, for example, in accordance with “JIS C 8715-1”.

An effective value Ua of an AC voltage when an effective value Ia of an AC current of a predetermined frequency (for example, a frequency between 1 Hz and 1 MHz) is applied to a unit cell is measured for a predetermined time (for example, between 1 second and 5 seconds). Alternatively, an effective value Ia of an AC current when an effective value Ua of an AC voltage of a predetermined frequency (for example, a frequency between 1 Hz and 1 MHz) is applied to a unit cell is measured for a predetermined time (for example, between 1 second and 5 seconds).

An AC internal resistance Rac is obtained by the following equation.

Rac=Ua/Ia

In the equation, Rac: AC internal resistance (Ω), Ua: effective value (V) of AC voltage, Ia: effective value (A) of AC current

All voltage measurements use terminals that are in a state independent from contacts that are used for supplying electricity.

In the case of performing measurement using an alternating current, it is desirable that an alternating peak voltage that is superimposed in applying a current be less than 20 mV.

This method measures an impedance. A real number component of the impedance is approximately equal to the internal resistance at a predetermined frequency.

The internal resistance may be a resistance that is measured using a direct current as described in “JIS C 8704-1”, or may be a pulse impedance, in addition to a direct current resistance and an alternating current impedance that are derived from the data on charging and discharging as described above.

The rate of deterioration can also be estimated using conductance that is a reciprocal of resistance and is measured by a battery tester or the like.

In the deterioration estimation device described above, in a case where the internal resistance or the conductance is inputted to the deterioration estimation device, the first estimation unit may input the derived internal resistance or conductance to a learning model that outputs the rate of deterioration so as to estimate the rate of deterioration of the lead-acid battery or the lead-acid battery module.

With such a configuration, the rate of deterioration of the battery can be easily and accurately estimated.

In the deterioration estimation device described above, in a case where a current or a voltage when discharging is performed until the lead-acid battery or the lead-acid battery module reaches a predetermined SOC is inputted to the deterioration estimation device, the first estimation unit may input the acquired current or voltage to a learning model that outputs the rate of deterioration so as to estimate the rate of deterioration of the lead-acid battery or the lead-acid battery module.

In the above-mentioned configuration, “a current and a voltage when discharging is performed until the lead-acid battery or the lead-acid battery module reaches a predetermined SOC” are a current and a voltage for deriving the internal resistance as described above.

With such a configuration, the rate of deterioration of the battery can be estimated without deriving the internal resistance.

The deterioration estimation device described above may include a second estimation unit that estimates the time series transition of the future rate of deterioration or the life based on the time series transition of the derived internal resistance or conductance or the time series transition of the estimated rate of deterioration.

With such a configuration, the lead-acid battery can be exchanged at an appropriate time by estimating the time series transition of the future rate of deterioration or the life.

In the deterioration estimation device described above, the second estimation unit may, when the internal resistance or conductance or the rate of deterioration is inputted to the deterioration estimation device in time series, estimate time series transition of the future rate of deterioration or life of the lead-acid battery or the lead-acid battery module by inputting the derived internal resistance or conductance or the estimated rate of deterioration to a recurrent neural network that outputs time-series transition of the future rate of deterioration or life.

With such a configuration, the transition of the rate of deterioration in future or the life of the battery can be easily and accurately estimated.

The deterioration estimation device described above may include a load adjustment unit that adjusts a load of the lead-acid battery or the lead-acid battery module corresponding to the rate of deterioration estimated by the first estimation unit.

As described above, there may be a case where the progress of deterioration differs among the lead-acid batteries due to temperatures of places where the lead-acid batteries are installed or irregularities in performance among the respective lead-acid batteries or the like. Accordingly, each time the lead-acid batteries deteriorate, it is necessary to exchange some lead-acid batteries and hence, the maintenance of the lead-acid batteries has been cumbersome. When the softening of the positive electrode progresses, a deterioration state of the lead-acid battery cannot be correctly estimated by a conventional diagnosis that is made based on an internal resistance of the lead-acid battery in a fully charged state. Accordingly, there is a concern that some lead-acid batteries that exceed a service limit are used in a connected state.

According to the configuration described above, based on the rate of deterioration that is estimated using an internal resistance in a deep discharged state, a control is performed so as to lower a load of the lead-acid battery that deteriorates quickly and to increase a load of the lead-acid battery that deteriorates slowly. Accordingly, it is possible to maintain a uniform deterioration rate among the lead-acid batteries in the entire power storage system. It is also possible to reduce the number of times that the lead-acid battery is exchanged. Further, it is also possible to reduce a risk that some lead-acid batteries are used beyond the limit. Also in the case of the lead-acid battery module, a load is similarly adjusted.

The deterioration estimation system according to the embodiment includes: the above-described deterioration estimation device; and a terminal that transmits a current, a voltage, the internal resistance or the conductance to the deterioration estimation device, wherein the deterioration estimation device transmits a rate of deterioration estimated by the first estimation unit to the terminal.

With such a configuration, the deterioration estimation device can estimate the rate of deterioration based on the current, the voltage, the internal resistance or the conductance that the terminal transmits, and can notify a user of the lead-acid battery of the result of the estimation.

In the above-described deterioration estimation system, the deterioration estimation device may include a charge control unit that performs refresh charging of other lead-acid batteries or other lead-acid battery modules using power when the power is discharged by the discharge control unit.

Lead-acid batteries used for power leveling are often operated in a partially charged state so as to be able to store surplus power. When the lead-acid battery is continuously used in a partially charged state, lead sulfate becomes coarse, and this causes the deterioration of the lead-acid battery called sulfation. When the sulfation occurs, charging and discharging of the lead-acid battery becomes difficult. Therefore, when the lead-acid battery is used in a partially charged state, charging (refresh charging) is often performed every several days to several weeks until the lead-acid battery is fully charged. The refresh charging often requires power from the outside. Accordingly, the refresh charging is not desirable in terms of cost and convenience.

According to the configuration described above, some lead-acid batteries or some lead-acid battery modules are discharged to estimate the rates of deterioration of the lead-acid batteries or the lead-acid battery module, and refresh charging of other lead-acid batteries or other lead-acid battery modules is performed using the power outputted at the time of performing the above-described discharging of some lead-acid batteries or some lead-acid battery modules. It is possible to perform refresh charging without requiring power from the outside. A power cost necessary for the refresh charging can be reduced. Further, even in a case where the power storage system is independent of a power system, it is possible to perform both maintenances, that is, the estimation of a deterioration state and refresh charging simultaneously.

In the deterioration estimation method according to this embodiment, an internal resistance or conductance in a case where the lead-acid battery or the lead-acid battery module that includes the plurality of lead-acid batteries is discharged until the lead-acid battery or the lead-acid battery module reaches a predetermined SOC is derived. Then, a rate of deterioration of the lead-acid battery or the lead-acid battery module is estimated based on the derived internal resistance or conductance.

With such a configuration, it is possible to estimate the rate of deterioration of the lead-acid battery in consideration of many deterioration modes such as the softening of a positive electrode, the corrosion of a current collector, and the depletion of electrolyte based on an internal resistance of the lead-acid battery when deep discharging is performed.

A computer program according to the embodiment allows a computer to execute processing that includes: deriving an internal resistance or conductance in a case where the lead-acid battery or the lead-acid battery module that includes a plurality of lead-acid batteries is discharged until the lead-acid battery or the lead-acid battery module reaches a predetermined SOC; and estimating a rate of deterioration of the lead-acid battery or the lead-acid battery module based on the derived internal resistance or conductance.

### Embodiment 1

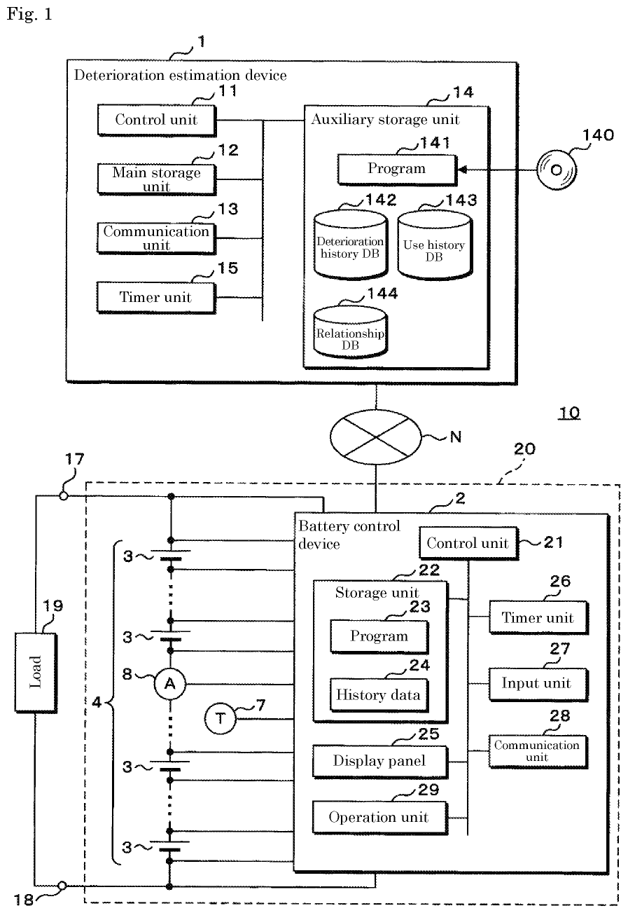

FIG. 1 is a block diagram illustrating an example of the configuration of a deterioration estimation system 10 according to an embodiment 1. In the deterioration estimation system 10, a battery control device 2 of a power storage system 20 is connected to the deterioration estimation device 1 via a network N such as the Internet. The battery control device 2 controls charging and discharging of a lead-acid battery (hereinafter, referred to as a battery) 3 and a lead-acid battery module (hereinafter, referred to as a battery module) 4. The deterioration estimation device 1 estimates the rate of deterioration of the battery 3 and the battery module 4 by controlling charging and discharging by the battery control device 2. The battery 3 includes a container, a positive electrode terminal, a negative electrode terminal, and a plurality of elements. In FIG. 1, the description is made with respect to a case where the power storage system 20 has one battery module 4 where a plurality of batteries 3 are connected to each other in series. However, the present invention is not limited to such a case, and the power storage system 20 may include a plurality of battery modules. The plurality of battery modules may be connected to each other in series or in parallel.

Hereinafter, the description is made with respect to a case where the deterioration estimation device 1 controls charging and discharging and estimates the rate of deterioration for each battery 3. The deterioration estimation device 1 can similarly estimate the rate of deterioration for each battery module 4.

The deterioration estimation device 1 acquires determination information such as a current and a voltage of the battery 3 from the battery control device 2, determines the rate of deterioration of the battery 3, and transmits the obtained result to the battery control device 2.

The deterioration estimation device 1 includes a control unit 11 that controls the entire device, a main storage unit 12, a communication unit 13, an auxiliary storage unit 14, and a timer unit 15. The deterioration estimation device 1 may be formed of one or a plurality of servers. The deterioration estimation device 1 may use a virtual machine instead of using a plurality of devices that perform distributed processing.

The control units 11 may be constituted of a central processing unit (CPU), a read only memory (ROM), a random access memory (RAM), and the like. The control unit 11 may include a graphics processing unit (GPU). The control unit 11 may use a quantum computer.

The main storage unit 12 is a temporary storage area such as a static random access memory (SRAM), a dynamic random access memory (DRAM), or a flash memory, and temporarily stores data necessary for the control unit 11 to execute arithmetic processing.

The communication unit 13 has a function of performing communication with battery control device 2 via the network N. The communication unit 13 can perform transmission and reception of desired information. Specifically, the communication unit 13 receives the determination information that is transmitted from the battery control device 2. The communication unit 13 transmits the determination result on the deterioration of the battery 3 to the battery control device 2.

The auxiliary storage unit 14 is a large-capacity memory, a hard disk, or the like. The auxiliary storage unit 14 stores a program necessary for the control unit 11 to execute processing, a program 141 for performing deterioration estimation processing that is described later, a deterioration history DB 142, a use history DB 143, and a relationship DB 144. The deterioration history DB 142 may be stored in another DB server.

Table 1 shows an example of a table stored in the deterioration history DB 142.

TABLE 1

| | Internal resistance (%) | | | Degree of |
|---|---|---|---|---|
| | First internal | Second internal | Third internal | deterioration |
| No. | resistance | resistance | resistance | (%) |
| 1 | 100 | 100 | 100 | 0 |
| 2 | 114 | 112 | 116 | 60 |
| 3 | 159 | 157 | 160 | 100 |
| . . . | . . . | . . . | . . . | . . . |

The deterioration history DB 142 stores a number column, an internal resistance column consisting of a first internal resistance column, a second internal resistance column, and a third internal resistance column, and a degree-of-deterioration column for each of a plurality of reached SOC (estimated SOC). The number column stores: the numbers of rows in a case where the determination of the deteriorations of the batteries 3 is performed with respect to a plurality of different batteries 3 or at different timings of the same batteries 3. The internal resistance column stores the first internal resistance, the second internal resistance, and the third internal resistance derived as described above in the internal resistance column. The internal resistance is represented by a ratio when the initial internal resistance of the battery 3 is set to 100%. The present invention is not limited to the case where the internal resistance column stores all of the first internal resistance, the second internal resistance, and the third internal resistance. The internal resistance column stores at least one of the first internal resistance, the second internal resistance, and the third internal resistance. In addition, the internal resistance column may store internal resistances other than the internal resistances described above.

Furthermore, the deterioration history DB 142 may store conductance instead of storing the internal resistance.

The degree-of-deterioration column stores degrees of deterioration obtained by measurement. The degree of deterioration corresponds to, for example, the state of health (SOH). The degree of deterioration when SOH is 100% is set to 0%, and the degree of deterioration when SOH is 0% is set to 100%. The SOH can be determined based on a characteristic that the battery 3 is expected to possess. For example, using a usable period as the reference, a rate of a remaining usable period at a point of time that the evaluation is made may be set as the SOH. Using a voltage during normal-temperature high-rate discharging as a reference, a voltage during the normal-temperature high-rate discharging at a point of time that the evaluation is made may be used for the evaluation of the SOH. The degree of deterioration when a capacity retention ratio becomes equal to or less than a threshold may be set to 100%. In any case, a case where the SOH is 0%, that is, a case where the degree of deterioration is 100%, indicates a state where the battery 3 lost its function.

The deterioration history DB 142 may store the internal resistance and the degree of deterioration for each type of the battery 3 or for each power storage system 20. When the SOC to which the battery 3 reaches is set to one, the deterioration history DB 142 stores the internal resistance and the degree of deterioration corresponding to the SOC.

Table 2 shows an example of a table stored in the use history DB 143.

| | Internal resistance (%) | | | |
|---|---|---|---|---|
| | First | Second | Third | Degree of |
| IDNo.1 | internal | internal | internal | deterioration |
| No. | resistance | resistance | resistance | (%) |
| 1 | 100 | 100 | 100 | 0 |
| 2 | 105 | 104 | 106 | 10 |
| . . . | . . . | . . . | . . . | . . . |
| 5 | | | | 50 |
| . . . | . . . | . . . | . . . | . . . |
| 10 | 159 | 157 | 160 | 100 |

The use history DB 143 stores a number column, an internal resistance column consisting of a first internal resistance column, a second internal resistance column, and a third internal resistance column, and a degree-of-deterioration column for each of a plurality of SOC (estimated SOC) for each battery 3. Table 2 illustrates the use histories of the batteries 3 each having an identification number No. 1 (ID No. 1). The internal resistance column consisting of the first internal resistance column, the second internal resistance column, and the third internal resistance column and the degree-of-deterioration column store the same contents as the internal resistance column consisting of the first internal resistance column, the second internal resistance column, and the third internal resistance column and the degree-of-deterioration column of the deterioration history DB 142.

The internal resistance column stores the first internal resistance, the second internal resistance, and the third internal resistance derived as described above in the internal resistance column. The present invention is not limited to the case where the internal resistance column stores all of the first internal resistance, the second internal resistance, and the third internal resistance. The internal resistance column stores at least one of the first internal resistance, the second internal resistance, and the third internal resistance. In addition, the internal resistance column may store internal resistances other than the internal resistances described above.

Furthermore, the deterioration history DB 142 may store conductance instead of storing the internal resistance.

The degree-of-deterioration column stores the degrees of deterioration that are estimated as described later.

The relationship DB 144 stores, for example, a relationship (a first degree-of-deterioration curve) between the degree of deterioration and the internal resistance that is derived for each type of the battery 3 based on the internal resistance and the degree of deterioration stored in the deterioration history DB 142.

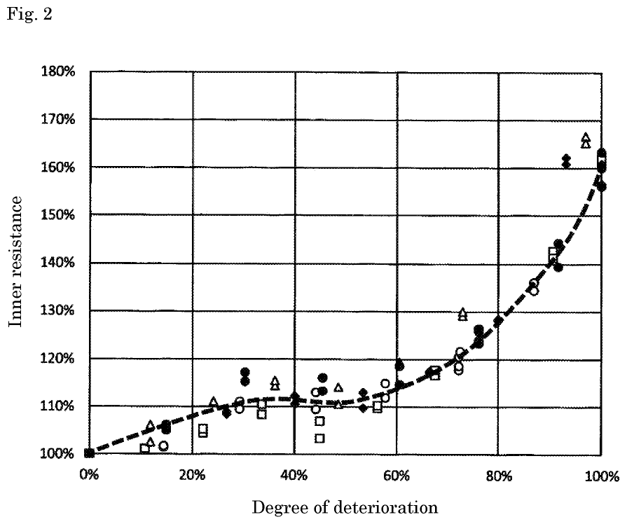

FIG. 2 shows an example of the first degree-of-deterioration curve when the estimated SOC is 30%. The degree of deterioration (%) is taken on an axis of abscissas, and

a ratio (%) of the internal resistance when the initial internal resistance of the battery 3 is set to 100% is taken on an axis of ordinates.

The relationship may be table data. Further, the relationship DB 144 may store a second degree-of-deterioration curve that indicates a time-series transition of a future degree of deterioration that is obtained as described later.

The program 141 that is stored in the auxiliary storage unit 14 may be provided by a recording medium 140 in which the program 141 is recorded in a readable manner. The recording medium 140 is, for example, a portable memory such as a USB memory, an SD card, a micro SD card, and a CompactFlash (a registered trademark). The program 141 recorded in the recording medium 140 is read from the recording medium 140 using a reading device (not illustrated) and is installed in the auxiliary storage unit 14. Furthermore, the program 141 may be provided by communication via the communication unit 13.

The timer unit 15 counts timings at which the estimation of the deterioration is performed.

The power storage system 20 supplies power to a thermal power generating system, a mega solar power generating system, a wind power generating system, a UPS, a stabilized power supply system for a railway, and the like. The power storage system 20 also stores power generated by these systems.

The power storage system 20 includes the battery module 4, the battery control device 2, a current sensor 8, and a temperature sensor 7.

The battery control device 2 includes a control unit 21, a storage unit 22, a display panel 25, a timer unit 26, an input unit 27, a communication unit 28, and an operation unit 29.

A load 19 is connected to the battery module 4 via terminals 17, 18.

The control unit 21 is constituted of, for example, a CPU, a ROM, a RAM, and the like, and controls an operation of the battery control device 2.

The control unit 21 monitors the states of the respective batteries 3.

The control unit 21 includes a voltage sensor that detects voltages of respective batteries 3, a flyback or forward converter, and the like. The control unit 21 controls refresh charging described later. In a case where the control unit 21 includes a flyback converter, a primary winding and a secondary winding of a transformer are connected with opposite polarities. Energy is stored in the winding on the primary side of the transformer from the battery 3 that performs discharging by turning on a transistor on a primary side. After turning off the transistor on the primary side, energy is discharged from the winding on the secondary side of the transformer, and charged energy is transferred to other batteries 3. In a case where the control unit 21 includes a forward converter, power is transmitted to other batteries 3 via a transformer at the time of discharging of the battery 3 that performs discharging.

The storage unit 22 stores: a program 23 necessary for the control unit 21 to execute deterioration determination processing; and charge-discharge history data 24. The program 23 may be provided by a recording medium in which the program 23 is recorded in a readable manner.

The charge-discharge history is an operation history of the battery 3. That is, the charge-discharge history is information that includes information indicating periods (use periods) during which the battery 3 is charged and discharged, information on charging or discharging performed by the battery 3 during the use period, and the like. The information indicating the use period of the battery 3 is information that includes information indicating a point of time that charging is started and a point of time that charging or discharging is finished, a cumulative use period during which the battery 3 is used, and the like. The information on charging or discharging performed by the battery 3 is information indicating a voltage, a rate, and the like used at the time of charging or discharging performed by the battery 3.

The display panel 25 may be formed of a liquid crystal panel, an organic electro luminescence (EL) display panel, or the like. The control unit 21 performs a control for displaying necessary information on the display panel 25.

The timer unit 26 performs time counting and counts estimation timings.

The input unit 27 receives inputting of detection results from the voltage sensor, the current sensor 8, and the temperature sensor 7.

The communication unit 28 has a function of performing communication with the deterioration estimation device 1 via a network N, and can perform the transmission and the reception of desired information.

The operation unit 29 is constituted of, for example, a hardware keyboard, a mouse, a touch panel, or the like. The operation unit 29 can perform a manipulation of icons and the like displayed on the display panel 25, inputting of characters or the like, and the like.

The current sensor 8 is connected in series with the battery module 4, and outputs a detection result corresponding to a current that flows through the battery module 4.

The temperature sensor 7 outputs a detection result corresponding to a temperature of a place where the battery module 4 is installed.

Hereinafter, a method in which the deterioration estimation device 1 estimates the degrees of deterioration of the respective batteries 3 of the battery module 4 is described.

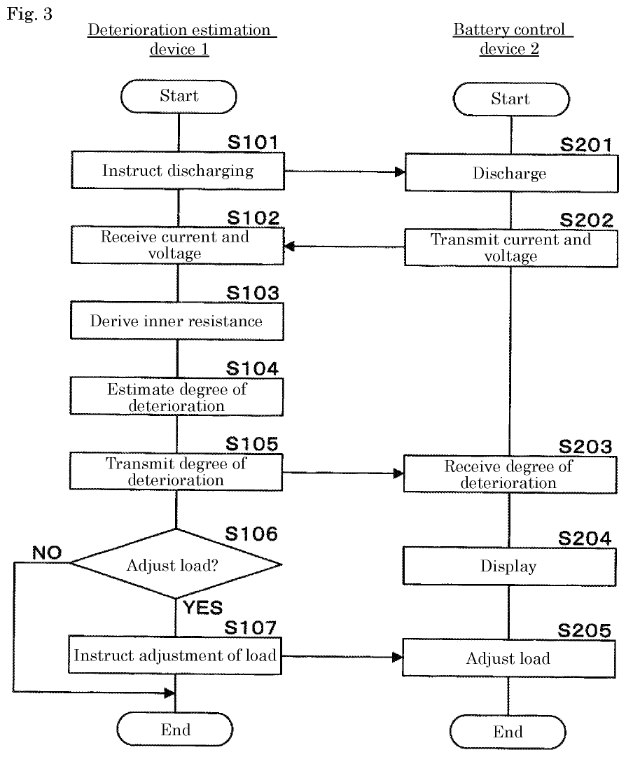

FIG. 3 is a flowchart illustrating steps of processing in which the control unit 11 estimates the degrees of deterioration of the batteries 3, and adjusts loads of the batteries 3.

The control unit 11 transmits an instruction to the control unit 21 so that the control unit 21 performs discharging until the batteries 3 reach a predetermined estimated SOC (S101). As the predetermined estimated SOC, 30% is named, for example.

The control unit 21 performs discharging until the batteries 3 reach a predetermined estimated SOC (S201).

The control unit 21 acquires a current and a voltage for deriving an internal resistance from the history data 24 as described above, and transmits the acquired current and voltage to the deterioration estimation device 1 (S202).

The control unit 11 receives the current and the voltage (S102).

The control unit 11 derives the internal resistance as described above (S103).

The control unit 11 estimates the degrees of deterioration and stores the estimated degrees of deterioration in the use history DB 143 (S104). The control unit 11 reads the first degree-of-deterioration curve corresponding to the reached estimated SOC from the relationship DB 144, and reads the internal resistance corresponding to the derived internal resistance. When there is no degree-of-deterioration curve corresponding to the estimated SOC, the degree of deterioration is obtained by interpolation calculation.

The control unit 11 transmits the degrees of deterioration to the battery control device 2 (S105).

The control unit 21 receives the degrees of deterioration (S203).

The control unit 21 displays the degrees of deterioration on the display panel 25 (S204).

The control unit 11 determines whether or not to adjust the load (S106). For example, when the degree of deterioration is equal to or greater than a threshold A or when the degree of deterioration is equal to or less than a threshold B, the control unit 11 determines to adjust the load. When the load is not adjusted (S106: NO), the processing finishes.

When the degree of deterioration is equal to or greater than the threshold Ain the case of adjusting the load (S106: YES), the control unit 11 transmits an instruction to the control unit 21 so that the control unit 21 decreases a charging/discharging amount of the battery 3, decreases the frequency of charging/discharging or the like. When the degree of deterioration is equal to or less than the threshold B, the control unit 11 transmits an instruction to the control unit 21 so that the control unit 21 increases a charging/discharging amount of the battery 3, increases the frequency of charging/discharging, or takes other operations, and finishes the processing (S107).

The control unit 21 adjusts the load of the battery 3 (S205), and the processing finishes.

When the control unit 21 does not adjust the load of the battery 3, the control unit 21 finishes the processing after step S204.

FIG. 4 is a graph showing a result of examining internal resistances of the respective batteries 1 to 6 whose capacities are lowered when the batteries 1 to 6 are deeply discharged until an estimated state of charge (SOC) reaches 30%. A ratio of the internal resistance when the initial internal resistance of the battery is set to 100% is taken on an axis of ordinates.

FIG. 5 is a graph showing a result of examining the internal resistances of the batteries 1 to 6 whose capacities are lowered in a fully charged state. A ratio of the internal resistance when the initial internal resistance of the battery is set to 100% is taken on an axis of ordinates.

It can be understood from FIG. 4 and FIG. 5 that the internal resistance during deep discharging accurately reflects the decrease in the capacities of the batteries.

As has been described above, according to this embodiment, it is possible to favorably estimate the rates of deterioration of the batteries 3 in consideration of many deterioration modes such as the softening of a positive electrode, the corrosion of a current collector, and the depletion of electrolyte based on the internal resistances of the batteries 3 when deep discharging is performed.

Then, by adjusting the loads of the batteries 3, it is possible to maintain a uniform deterioration speed among the batteries 3 in the entire power storage system 20. Accordingly, it is possible to reduce the number of times that the batteries 3 are exchanged. Further, it is also possible to reduce a risk that some batteries 3 are used beyond the use limit.

The control unit 21 may derive the internal resistances, and may transmit the internal resistances to the deterioration estimation device 1. The control unit 21 may notify the degree of deterioration to an operator of the power storage system 20 by voice instead of making the display panel 25 display the degree of deterioration.

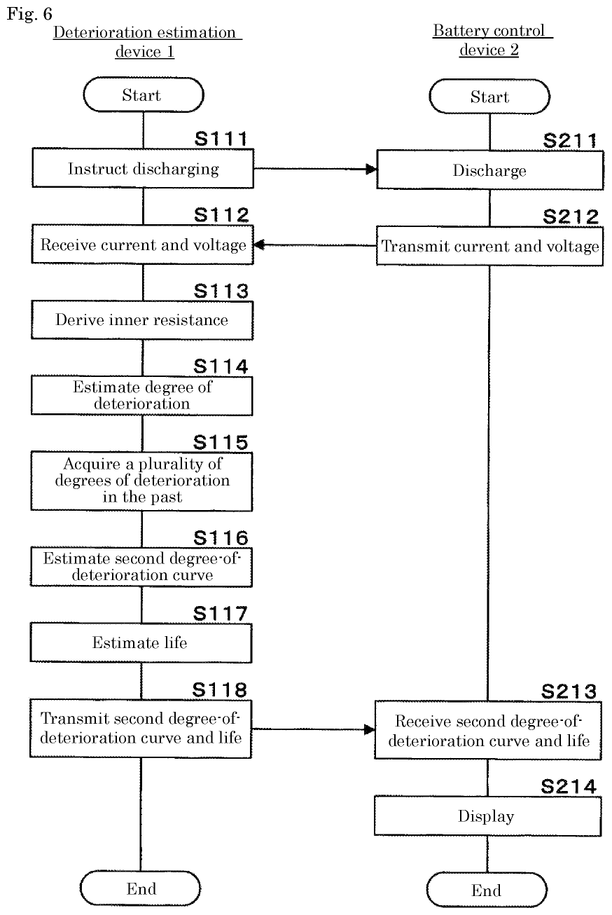

FIG. 6 is a flowchart illustrating steps of processing in which the control unit 11 estimates the degree of deterioration of the battery 3, and estimates the transition of the degree of deterioration of the battery 3 and a life of the battery 3.

The control unit 11 transmits an instruction to the control unit 21 so that the control unit 21 performs discharging until the batteries 3 reach a predetermined estimated SOC (S111).

The control unit 21 performs discharging until the batteries 3 reach a predetermined estimated SOC (S211).

The control unit 21 acquires a current and a voltage from the history data 24, and transmits the acquired current and voltage to the deterioration estimation device 1 (S212).

The control unit 11 receives the current and the voltage (S112).

The control unit 11 derives the internal resistances (S113).

The control unit 11 estimates the degrees of deterioration (S114). The control unit 11 reads the first degree-of-deterioration curve corresponding to the reached estimated SOC from the relationship DB 144, estimates the degree of deterioration based on the derived internal resistance, and stores the degree of deterioration in the use history DB 143 (S115). When there is no first degree-of-deterioration curve corresponding to the estimated SOC, the degree of deterioration is obtained by interpolation calculation.

The control unit 11 acquires a plurality of past degrees of deterioration (S115).

The control unit 11 estimates a time-series transition of the degree of deterioration (second degree-of-deterioration curve: relationship between time and degree of deterioration) and stores the estimated transition of the degree of deterioration in the relationship DB 144 (S116). The control unit 11 derives the second degree-of-deterioration curve using a method such as curve approximation by a least squares method or a Kalman filter based on the currently estimated degrees of deterioration and the plurality of past estimated degrees of deterioration. The past second degree-of-deterioration curve may be stored in the relationship DB 144 based on the data of the deterioration history DB 142, and the second degree-of-deterioration curve in the current estimation may be derived with reference to the past second degree-of-deterioration curve.

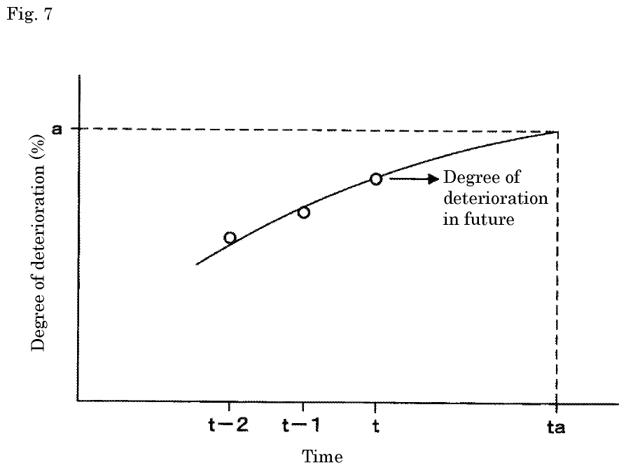

As illustrated in FIG. 7, the degrees of deterioration estimated at the current estimated point of time t, at the previous estimated point of time t−1, and at the estimation point of time t−2 that is the second most recent point of time are plotted to estimate a future second degree-of-deterioration curve. The number of plots is not limited to the number of plots adopted in the case illustrated in FIG. 7.

The control unit 11 estimates the life (S117). The control unit 11 acquires the time tₐ when the degree of deterioration becomes a in the estimated second degree-of-deterioration curve as the life (exchange time).

The control unit 11 transmits the second degree-of-deterioration curve and the life to the battery control device 2 (S118), and finishes the processing.

The control unit 21 receives the second degree-of-deterioration curve and the life (S213), displays the curve and the life on the display panel 25 (S214), and finishes the processing.

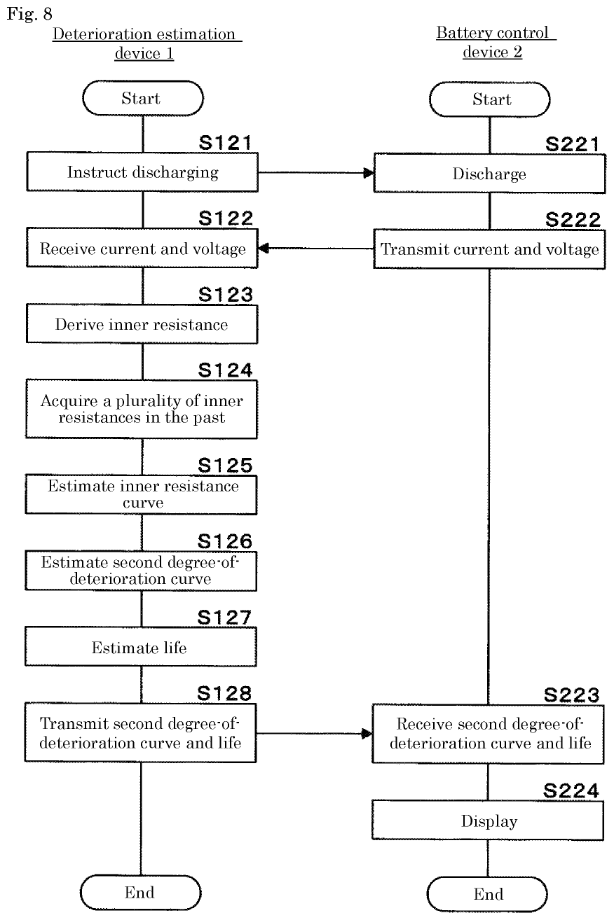

FIG. 8 is a flowchart of processing according to a modification illustrating steps of processing in which the control unit 11 estimates the transition of an internal resistance of the battery 3, and estimates the transition of the degree of deterioration and the life of the battery 3.

The control unit 11 transmits an instruction to the control unit 21 so that the control unit 21 performs discharging until the batteries 3 reach a predetermined estimated SOC (S121).

The control unit 21 performs discharging until the batteries 3 reach the predetermined estimated SOC (S221).

The control unit 21 acquires a current and a voltage from the history data 24, and transmits the acquired current and voltage to the deterioration estimation device 1 (S222).

The control unit 11 receives the current and the voltage (S122).

The control unit 11 derives the internal resistance, and stores the internal resistance in the use history DB 143 (S123).

The control unit 11 acquires a plurality of past internal resistances (S124).

The control unit 11 estimates a time-series transition of the internal resistance (internal resistance curve), and stores the estimated transition in the relationship DB 144 (S125). The control unit 11 derives an internal resistance curve using a method such as curve approximation based on the internal resistance derived this time and a plurality of internal resistances derived in the past. The past internal resistance curves may be stored in the relationship DB 144 based on the data of the deterioration history DB 142, and the internal resistance curve in the current estimation may be derived with reference to the past internal resistance curves.

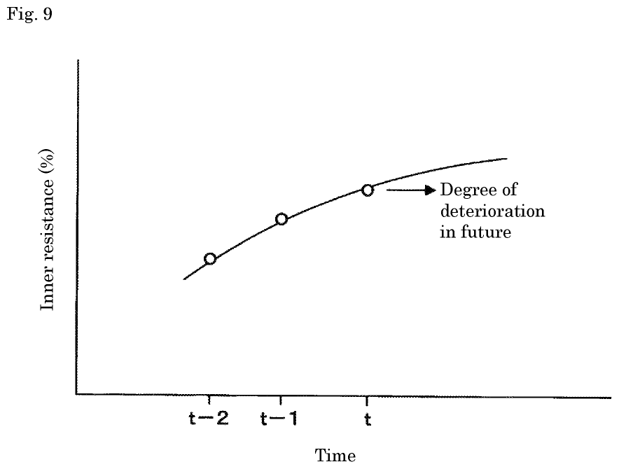

As illustrated in FIG. 9, the internal resistances estimated at the current estimated point of time t, at the previous estimated point of time t−1, and at the estimation point of time t−2 that is the second most recent point of time are plotted to estimate a future internal resistance curve.

The control unit 11 estimates the second degree-of-deterioration curve based on the estimated internal resistance curve, and stores the estimated second degree-of-deterioration curve in the use history DB 143 (S126). The control unit 11 estimates the second degree-of-deterioration curve based on the internal resistance curve estimated this time and the first degree-of-deterioration curve (the relationship between the degree of deterioration and the internal resistance) stored in the relationship DB 144.

The control unit 11 acquires the time tₐ when the rate of deterioration becomes a as the life (exchange time) (S127).

The control unit 11 transmits the second degree-of-deterioration curve and the life to the battery control device 2 (S128), and finishes the processing.

The control unit 21 receives the second degree-of-deterioration curve and the life (S223), displays the curve and the life on the display panel 25 (S224), and finishes the processing.

According to this embodiment, the battery 3 can be exchanged at an appropriate time by estimating the second degree-of-deterioration curve or the life.

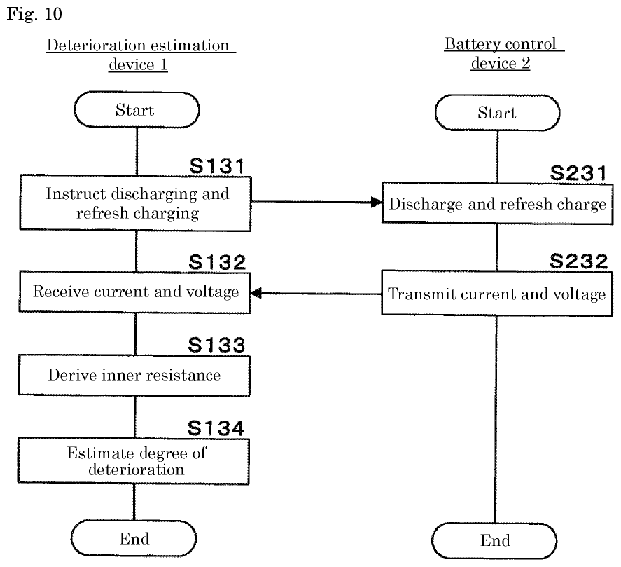

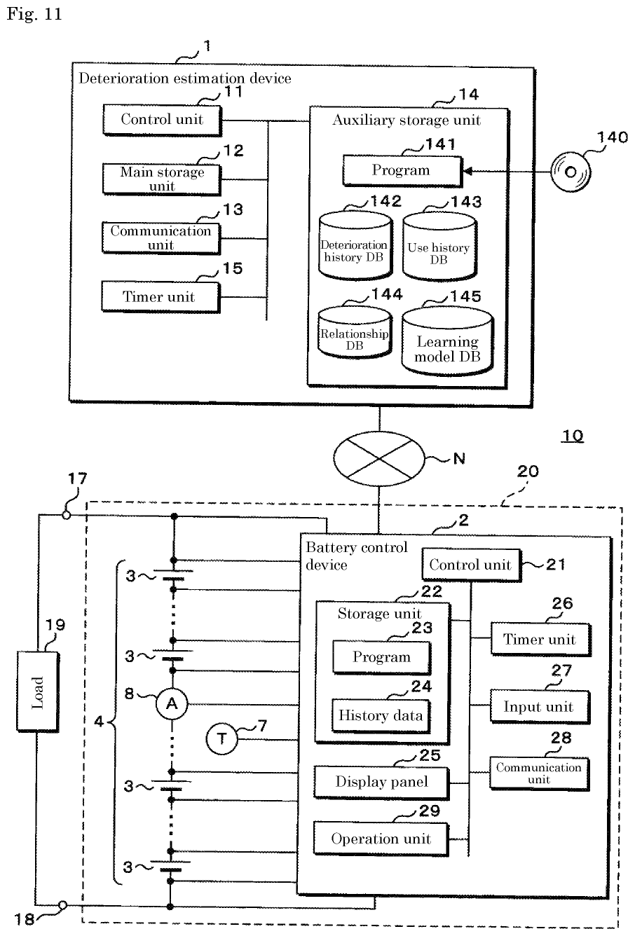

FIG. 10 is a flowchart illustrating steps of processing in a case where refresh charging is simultaneously performed when the control unit 11 performs discharging until the batteries reach a predetermined estimated SOC.

The control unit 11 transmits an instruction to the control unit 21 so that the control unit 21 performs discharging of the batteries 3 until the batteries 3 reach a predetermined estimated SOC, and at the same time, performs refresh charging of other batteries 3 by using the discharged power (S131).

The control unit 21 performs discharging of the batteries 3 until the batteries 3 reach a predetermined estimated SOC, and at the same time, performs refresh charging of other batteries 3 by using the discharged power (S231).

The control unit 21 acquires a current and a voltage from the history data 24, and transmits the acquired current and voltage to the deterioration estimation device 1 (S232).

The control unit 11 receives the current and the voltage (S132).

The control unit 11 derives the internal resistances (S133).

The control unit 11 estimates the degrees of deterioration (S134).

Hereinafter, the same processing as described above is performed.

According to this embodiment, it is possible to perform refresh charging without requiring power from the outside. A power cost necessary for the refresh charging can be reduced. Further, even in a case where the power storage system 20 is independent of a power system, it is possible to perform both maintenances, that is, the estimation of a deterioration state and refresh charging simultaneously.

In the present embodiment, the case is described where the deterioration estimation device 1 estimates the degree of deterioration of the battery 3, adjusts the load of the battery 3, estimates the second degree-of-deterioration curve and the life, and controls the refresh charging. However, the present invention is not limited to such a case. Without being remotely operated by the deterioration estimation device 1, the battery control device 2 may estimate the degree of deterioration, may adjust the load of the battery 3, estimate the second degree-of-deterioration curve and the life, and may control the refresh charging.

### Embodiment 2

FIG. 11 is a block diagram illustrating the configuration of a deterioration estimation system 10 according to an embodiment 2.

The deterioration estimation system 10 according to the embodiment 2 has the same configuration as the deterioration estimation system 10 according to the embodiment 1 except that an auxiliary storage unit 14 stores a learning model DB 145. The learning model DB 145 stores learning models 146 generated for a plurality of respective reached SOCs (estimated SOCs).

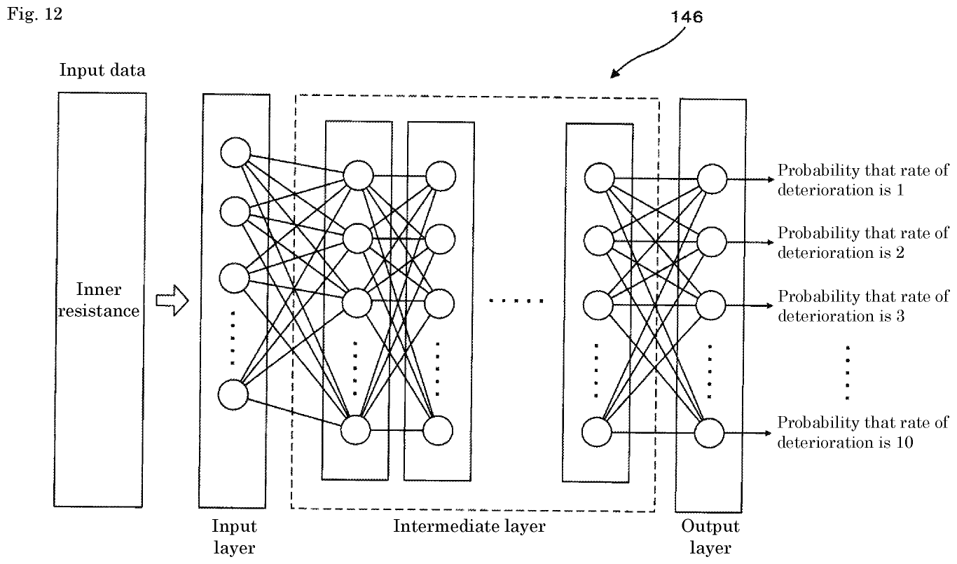

FIG. 12 is a schematic view illustrating one example of the learning model 146.

The learning model 146 is a learning model expected to be used as a program module that is a part of artificial intelligence software. The learning model 146 can use a multilayer neural network (deep learning). For example, the learning model 146 can use a convolutional neural network (CNN). However, the learning model 146 may also use other neural networks. Other machine learnings may be used. The control unit 11 operates in such a manner that the control unit 11 applies an arithmetic operation to an internal resistance inputted to an input layer of the learning model 146 in accordance with an instruction from the learning model 146, and outputs the rate of deterioration and the probability of the rate of deterioration as a determination result. In the case where the learning model 146 uses CNN, an intermediate layer includes a convolution layer, a pooling layer and a fully connected layer. The number of nodes (neurons) is also not limited to the number adopted in the case illustrated in FIG. 12.

The rate of deterioration is represented by, for example, a numerical values of 10 stages from 1 to 10. The rate of deterioration is determined based on a range of the degree of deterioration. For example, the rate of deterioration “1” is given to the SOH that falls within a range of 90 to 100% of the SOH, and the rate of deterioration “10” is given to the SOH that falls within a range of 0 to 10% of the SOH.

One or a plurality of nodes exist in an input layer, an output layer and the intermediate layer. The nodes in each layer are coupled to the nodes existing in preceding and succeeding layers in one direction with desired weighting respectively. A vector having the same number of components as the number of nodes in the input layer is given as input data to the learning model 146 (input data for learning and input data for estimation). The learned input data includes at least the internal resistance at the reached SOC (estimated SOC). The input data may include, besides the internal resistance, at least one of an internal resistance in a fully charged state, an open circuit voltage, a discharge capacity, a discharge voltage (an estimated value of the discharge capacity based on the discharge voltage), and a temperature obtained by a temperature sensor 7.

The internal resistance is inputted to the input layer of the learned learning model 146. When data that are given to the respective nodes in the input layer are given to the first intermediate layer by inputting, an output from the intermediate layer is calculated using weighting and an activation function. Next, the calculated values are given to the next intermediate layer. Then, in the substantially same manner, the calculated values are successively transmitted to subsequent layers (low-order layers) until an output from the output layer is obtained. Here, all weightings for coupling the nodes to each other are calculated by a learning algorithm.

The output layer of the learning model 146 generates the rate of deterioration and the probability of the rate of deterioration as output data.

the output layer outputs the output data as follows, for example.

Probability that the rate of deterioration is 1 . . . 0.01

Probability that the rate of deterioration is 2 . . . 0.90

Probability that the rate of deterioration is 3 . . . 0.02

. . .

Probability that the rate of deterioration is 10 . . . 0.001

The control unit 11 acquires a numerical value of the rate of deterioration having the maximum probability.

Instead of the rate of deterioration, the output layer may output the degree of deterioration described above in the form of the degree of deterioration and its probability in increments of 1% in a range of, for example, 0% to 100%.

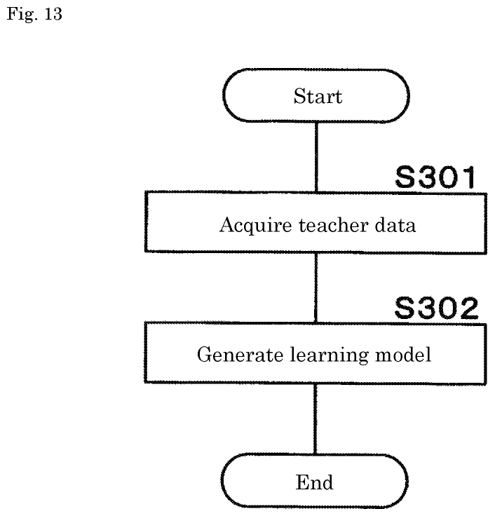

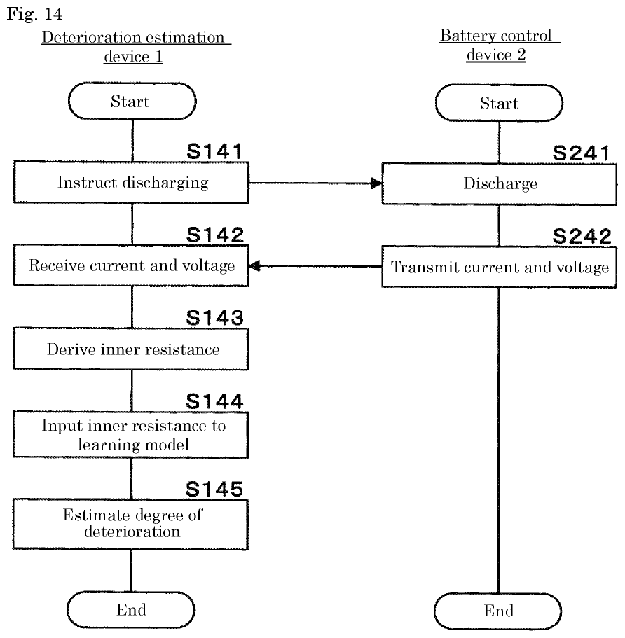

FIG. 13 is a flowchart illustrating steps of processing for generating the learning model 146 by the control unit 11.

The control unit 11 reads the deterioration history DB 142 and acquires teacher data in which the internal resistance of each row in a predetermined estimated SOC is associated with the rate of deterioration based on the degree of deterioration (S301).

Using the teacher data, the control unit 11 generates the learning model 146 (learned type) that outputs the probability of the rate of deterioration when the internal resistance is inputted (S302). Specifically, the control unit 11 inputs teacher data to the input layer, performs arithmetic processing in the intermediate layer, and acquires the probability of rate of deterioration from the output layer.

The control unit 11 compares the determination result of the rate of deterioration outputted from the output layers with information labeled to the internal resistance in the teacher data, that is, a correct value. Then, the control unit 11 optimizes parameters used in the arithmetic processing performed in the intermediate layers so that an output value from the output layer approaches the correct value. The parameters are, for example, weighting (a coupling coefficient), a coefficient of an activation function and the like described above. A method of optimizing the parameters is not particularly limited. However, for example, the control unit 11 optimizes various parameters using an error back propagation method.

The control unit 11 stores the generated learning model 146 in the auxiliary storage unit 14, and finishes the series of processing.

FIG. 14 is a flowchart illustrating steps of processing in which the control unit 11 estimates the rate of deterioration of the battery 3.

The control unit 11 transmits an instruction to the control unit 21 so that the control unit 21 performs discharging until the batteries 3 reach a predetermined estimated SOC (S141).

The control unit 21 performs discharging until the batteries 3 reach the predetermined estimated SOC (S241).

The control unit 21 acquires a current and a voltage from the history data 24, and transmits the acquired current and voltage to the deterioration estimation device 1 (S242).

The control unit 11 receives the current and the voltage (S142).

The control unit 11 derives the internal resistances (S143).

The control unit 11 selects the learning model 146 corresponding to the estimated SOC and inputs the internal resistance to the learning model 146 (S144).

The control unit 11 estimates a numerical value of the rate of deterioration having the highest probability among the degrees of deterioration that the learning model 146 outputs as a

rate of deterioration at the current estimation time (S145), and finishes the processing.

After the estimation of the rate of deterioration is performed, the succeeding processing after S105 illustrated in FIG. 5 can be performed.

When there is no learning model 146 that corresponds to the estimated SOC, the rate of deterioration is estimated using the learning models 146 of two estimated SOCs close to the estimated SOC, and the rate of deterioration is obtained by interpolation calculation.

According to the present embodiment, the rate of deterioration of the battery can be easily and accurately estimated.

The control unit enables relearning of the learning model 146 based on the rate of deterioration estimated using the learning model 146 and the rate of deterioration obtained by actual measurement so that the reliability of the estimation of the rate of deterioration is improved. The actually measured degree of deterioration is obtained in the predetermined row of the use history DB 35, and when the estimated rate of deterioration and the rate of deterioration based on the actually measured degree of deterioration agree with each other, relearning is performed by inputting a large number of teacher data in which the rate of deterioration is associated with the internal resistance in the row so that the probability of the rate of deterioration can be improved. When the estimated rate of deterioration and the actually measured rate of deterioration do not agree with each other, relearning is performed by inputting the teacher data where the actually measured rate of deterioration is associated with the internal resistance.

The learning model 146 may be a learning model that is learned using the internal resistance and the reached SOC in the reached SOC (estimated SOC) and the label data indicating the rate of deterioration as the teacher data, and outputs the rate of deterioration when the internal resistance and the reached SOC are inputted. In this case, it is not necessary to generate a plurality of learning models unlike the above-mentioned case.

### Embodiment 3

A deterioration estimation system 10 according to the embodiment 3 has the same configuration as the deterioration estimation system 10 according to the embodiment 2 except that an auxiliary storage unit 14 stores a learning model 147, and a history of a temperature is also stored in a history data 24.

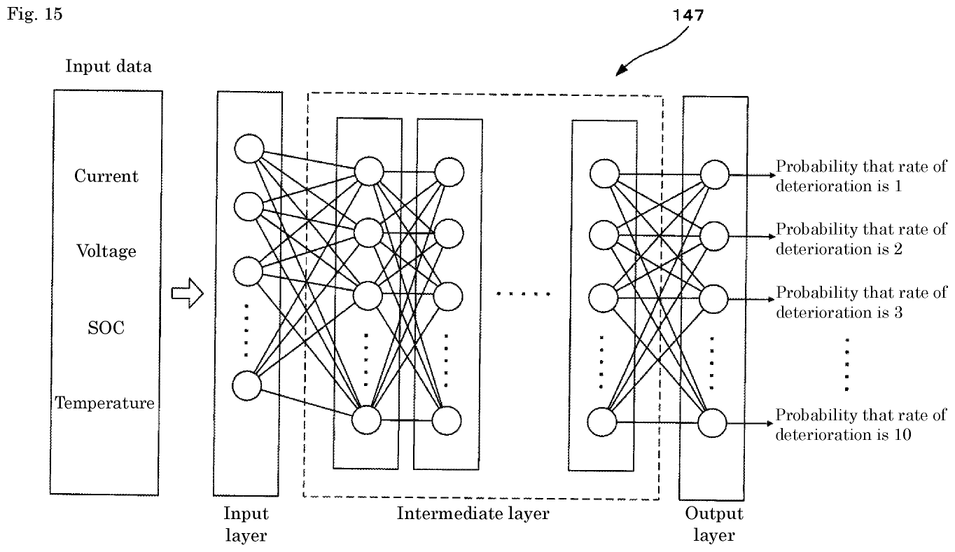

FIG. 15 is a schematic view illustrating one example of the learning model 147 according to the embodiment 3.

The learning model 147 has the same configuration as the learning model 146 except that the input data is different from the input data of the learning model 146.

A current, a voltage, a SOC (reached estimated SOC), and a temperature are inputted to an input layer of the learned learning model 147. The current and the voltage are obtained when a battery 3 is deeply discharged, and the current and the voltage are used when an internal resistance described above is derived. With respect to input data, when data given to respective nodes in the input layer are given to a first intermediate layer by inputting, an output from the intermediate layer is calculated using weighting and an activation function. The calculated values are given to the next intermediate layer. Then, in the substantially same manner, the calculated values are successively transmitted to subsequent layers (low-order layers) until an output from the output layer is obtained. All weightings for coupling the nodes to each other are calculated by a learning algorithm. The input data is not limited to the case where the input data includes all of a current, a voltage, a SOC, and a temperature. It is sufficient that the input data includes at least a current, a voltage, and an SOC. The input data includes other information that can be calculated based on a current, a voltage, a temperature and the like. That is, the input data may include histories or the like of a lifetime effective discharge capacity, a lifetime effective charge capacity, a lifetime effective overcharge capacity, a temperature cumulative value, a standing time, an SOC stay time, and the like. When a plurality of learning models are generated corresponding to a plurality of SOCs as in the case of the second embodiment, learning models that correspond to the SOCs are selected and hence, and it is unnecessary to input the SOCs.

The output layer of the learning model 147 generates the rates of deterioration and probabilities of the degrees of deterioration as output data.

the output layer outputs the output data as follows, for example.

Probability that the rate of deterioration is 1 . . . 0.01

Probability that the rate of deterioration is 2 . . . 0.90

Probability that the rate of deterioration is 3 . . . 0.02

. . .

Probability that the rate of deterioration is 10 . . . 0.001

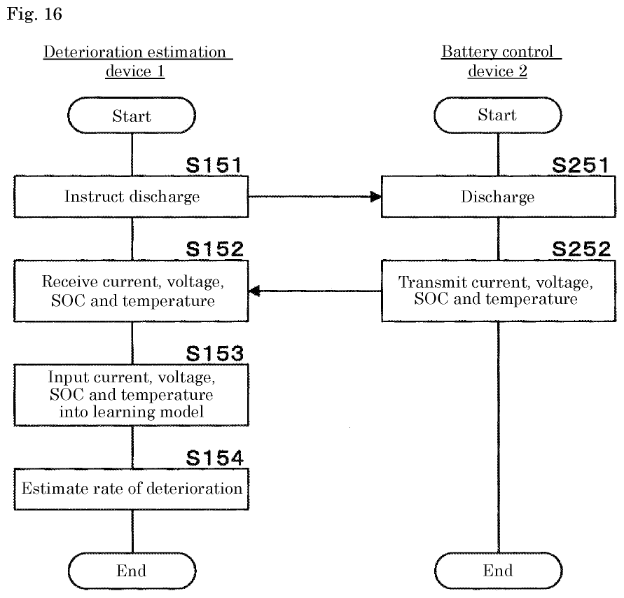

FIG. 16 is a flowchart illustrating steps of processing in which the control unit 11 estimates the rate of deterioration of the batteries 3.

The control unit 11 transmits an instruction to the control unit 21 so that the control unit 21 performs discharging until the batteries 3 reach a predetermined estimated SOC (S151).

The control unit 21 performs discharging until the batteries 3 reach the predetermined estimated SOC (S251).

The control unit 21 acquires a current, a voltage, a SOC and a temperature from the history data 24, and transmits the acquired current, voltage, SOC and temperature to the deterioration estimation device 1 (S252).

The control unit 11 receives the current, the voltage, the SOC, and the temperature (S152).

The control unit 11 inputs the current, the voltage, the SOC, and the temperature to the learning model 147 (S153).

The control unit 11 determines a numerical value of the rate of deterioration having the highest probability among the rates of deterioration that the learning model 147 outputs as a rate of deterioration (S154), and finishes the processing.

According to the present embodiment, the rate of deterioration of the battery can be easily and accurately estimated.

The present embodiment is not limited to the case where the input data includes a temperature.

### Embodiment 4

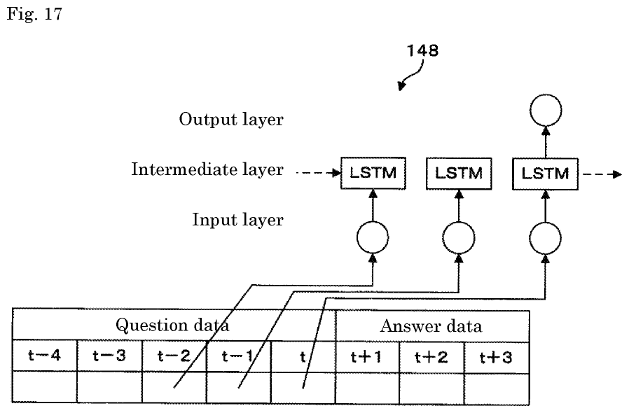

FIG. 17 is an explanatory table relating to processing of generating a learning model 148 according to an embodiment 4. The deterioration estimation device 1 constructs (generates) a neural network in which the plurality of degrees of deterioration in the time series are inputted and the degrees of deterioration in the plurality of points of time in the future are outputted by performing learning based on teacher data in which a plurality of degrees of deterioration in the time series are used as problem data and the degrees of deterioration in the plurality of points in the future are used as answer data. As described above, the degree of deterioration corresponds to, for example, the state of health (SOH). The degree of deterioration when SOH is 100% is set to 0%, and the degree of deterioration when SOH is 0% is set to 100%. The SOH can be determined based on a characteristic that the battery 3 is expected to possess. As examples of the SOH, a capacity retention ratio is named, for example. Further, in a case where a ratio of a usable period remaining at a point of time of evaluation (a remaining life rate) is set as a degree of deterioration using the usable period as the reference, the remaining life rate is outputted from the output layer in time series.

Instead of the degrees of deterioration, as in the case of the embodiment 2 and the embodiment 3, the rates of deterioration in a plurality of stages may be used

The plurality of degrees of deterioration in time series means a plurality of ratios of deterioration in time series from the past to the current estimation point of time in the same battery 3. The degree of deterioration corresponds to the ratio of deterioration estimated based on the internal resistance. The internal resistance is derived from a current and a voltage. The degrees of deterioration at a plurality of future points of time mean the degrees of deterioration at a plurality of future points of time such as the next highest point of time and the next highest point of time after the next highest point of time with respect to the current estimation point of time.

The input layer includes a single neuron or a plurality of neurons that receive a plurality of degrees of deterioration in time series, and passes the inputted respective degrees of deterioration to the intermediate layer. The intermediate layer includes an autoregressive layer that includes a plurality of neurons. The autoregressive layer is implemented as, for example, a long short term memory (LSTM) type. A neural network that includes such an autoregressive layer is referred to as a recurrent neural network (RNN). The intermediate layer outputs amounts of change of a plurality of respective degrees of deterioration sequentially inputted to the intermediate layer in time series. The output layer includes one or a plurality of neurons that receive degrees of deterioration at a plurality of points of time in the future, and outputs the degrees of deterioration at the plurality of points of time in the future based on the amounts of change of the plurality of respective degrees of deterioration outputted from the intermediate layer. Such learning for the RNN is performed using, for example, a backpropagation through time (BPTT) algorithm.

The teacher data may be stored in an array format. In a case where the teacher data is in an array format, for example, the values of respective elements from 0 to 4 (t−4 to t) of the array number may be used as the problem data, and the values of the elements from 5 to 7 (t+1 to t+3) of the array number may be used as the answer data. The problem data in time-series (t−2, t−1, t) inputted from the input layer is sequentially transferred to the LSTM (autoregressive layer), and the LSTM (autoregressive layer) outputs the output value to the output layer and its own layer. Accordingly, the series information that includes the changes with time and the sequence can be processed.

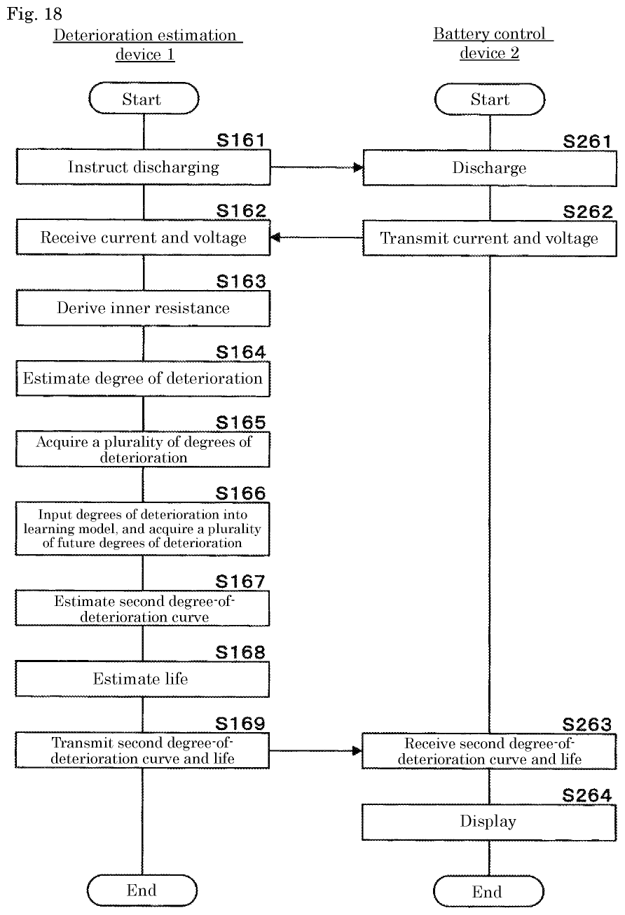

FIG. 18 is a flowchart illustrating steps of processing in which a control unit 11 estimates the degree of deterioration of the battery 3, and estimates the transition of the degree of deterioration of the battery 3 and a life of the battery 3. Hereinafter, the description is made by taking a case where SOH is a capacity retention ratio, and the degree of deterioration of SOH of 100% is set to 0% as an example.

The control unit 11 transmits an instruction to the control unit 21 so that the control unit 21 performs discharging until the batteries 3 reach a predetermined estimated SOC (S161).

The control unit 21 performs discharging until the batteries 3 reach the predetermined estimated SOC (S261).

The control unit 21 acquires a current and a voltage from the history data 24, and transmits the acquired current and voltage to the deterioration estimation device 1 (S262).

The control unit 11 receives the current and the voltage (S162).

The control unit 11 derives the internal resistances (S163).

The control unit 11 estimates the degree of deterioration based on the derived internal resistance, and stores the degree of deterioration in the use history DB 143 (S164). The control unit 11 reads the relationship DB 144, and estimates the degree of deterioration with reference to the first degree-of-deterioration curve based on the derived internal resistance.

The control unit 11 acquires a plurality of degrees of deterioration (S165).

The control unit 11 inputs a plurality of degrees of deterioration in time series to the learned learning model 148 and acquires a plurality of future degrees of deterioration (S166).

The control unit 11 estimates the transition of the degrees of deterioration in time series (second degree-of-deterioration curve) as described above based on the plurality of degrees of deterioration in the past, at the present, and in the future, and stores the estimated transition of the degrees of deterioration in the relationship DB 144 (S167).

The control unit 11 estimates the life (S168). The control unit 11 acquires the time tₐ when the degree of deterioration becomes a threshold a as the life (an exchange time).

The control unit 11 transmits the second degree-of-deterioration curve and the life to the battery control device 2 (S169), and finishes the processing.

The control unit 21 receives the second degree-of-deterioration curve and the life (S263), displays the second degree-of-deterioration curve and the life on the display panel 25 (S264), and finishes the processing.

When the degree of deterioration is the above-described remaining life rate, the future remaining life rate, that is, the transition of the life is acquired by inputting the degree of deterioration to the learning model 148 in step S166.

According to the present embodiment, the time-series transition of the degree of deterioration or the life of the battery in future can be easily and accurately estimated.

### Embodiment 5

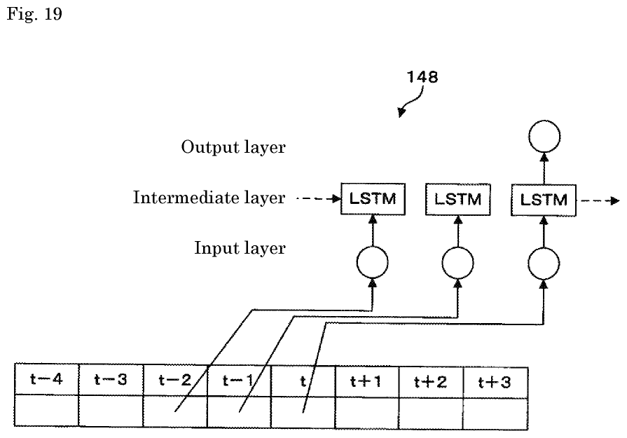

FIG. 19 is an explanatory table illustrating the configuration of a learning model (learned) 149 according to an embodiment 5. A neural network in which the plurality of internal resistances in the time series are inputted and the degrees of deterioration in the plurality of points of time in the future are outputted is constructed by performing learning based on teacher data in which internal resistances at a plurality of points of time in the time series are used as problem data and the degrees of deterioration in the plurality of points of time in the future are used as answer data.

The plurality of internal resistances in time series mean a plurality of internal resistances in time series from the past to the current estimation point of time in the same battery 3. The internal resistance is derived from a current and a voltage. The degrees of deterioration at a plurality of future points of time mean the degrees of deterioration at a plurality of future points of time such as the next highest point of time and the next highest point of time after the next highest point of time with respect to the current estimation point of time.

The input layer includes a single neuron or a plurality of neurons that receive a plurality of internal resistances in time series, and passes the inputted respective internal resistances to the intermediate layer. The intermediate layer includes an autoregressive layer that includes a plurality of neurons. The autoregressive layer is implemented as, for example, an LSTM type. The intermediate layer outputs amounts of change of a plurality of respective internal resistances sequentially inputted to the intermediate layer in time series. The output layer includes a plurality of neurons that correspond to degrees of deterioration at a plurality of points of time in the future, and outputs the degrees of deterioration at the plurality of points of time in the future based on the amounts of change of the plurality of respective internal resistances outputted from the intermediate layer. Such learning for the RNN is performed using, for example, the BPTT algorithm.

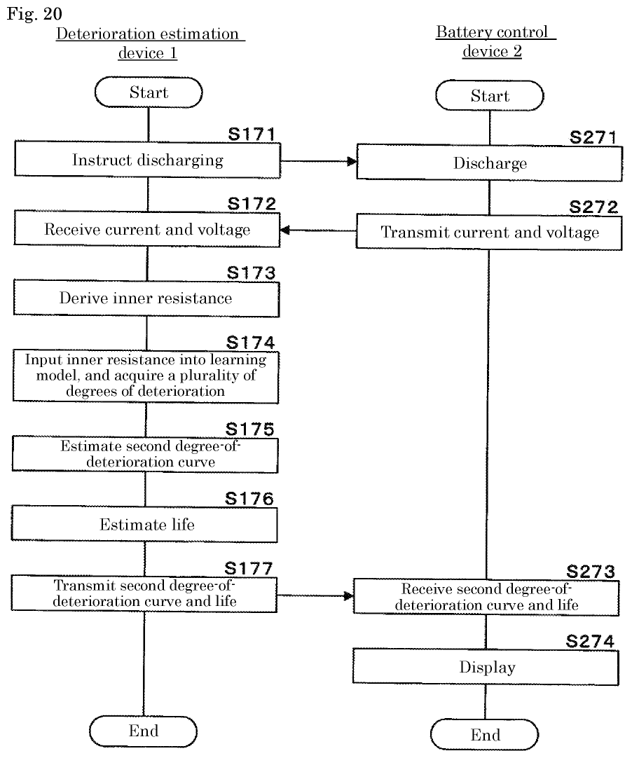

FIG. 20 is a flowchart illustrating steps of processing in which the control unit 11 derives an internal resistance of the battery 3, and estimates the transition of the degree of deterioration and a life of the battery 3.

The control unit 11 transmits an instruction to the control unit 21 so that the control unit 21 performs discharging until the batteries 3 reach a predetermined estimated SOC (S171).

The control unit 21 performs discharging until the batteries 3 reach the predetermined estimated SOC (S271).

The control unit 21 acquires a current and a voltage from the history data 24, and transmits the acquired current and voltage to the deterioration estimation device 1 (S272).

The control unit 11 receives the current and the voltage (S172).

The control unit 11 derives the internal resistances (S173).

The control unit 11 inputs the internal resistances to the learning model 149 and acquires a plurality of future degrees of deterioration (S174).

The control unit 11 estimates the transition of the degrees of deterioration in time series (second degree-of-deterioration curve) based on the plurality of degrees of deterioration in the past, at the present, and in the future (S175).

The control unit 11 estimates the life (S176). The control unit 11 acquires the time tₐ when the degree of deterioration becomes a threshold a as the life (an exchange time).

The control unit 11 transmits the second degree-of-deterioration curve and the life to the battery control device 2 (S177), and finishes the processing.

The control unit 21 receives the second degree-of-deterioration curve and the life (S273), displays the second degree-of-deterioration curve and the life on the display panel 25 (S274), and finishes the processing.

According to the present embodiment, the time-series transition of the degree of deterioration or the life of the battery in future can be easily and accurately estimated based on the internal resistance without deriving the degree of deterioration.

### Embodiment 6

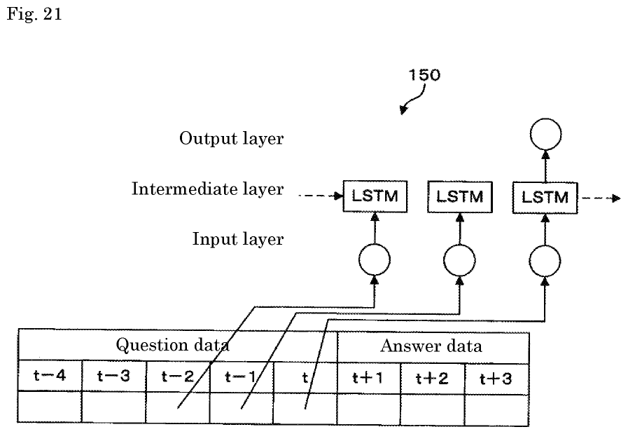

FIG. 21 is an explanatory table relating to processing of generating a learning model 150 according to an embodiment 6. The learning model 150 has the same configuration as the learning model 148, and is different from the learning model 148 in that internal resistances are inputted to an input layer in time series, and a plurality of future internal resistances are outputted from an output layer.

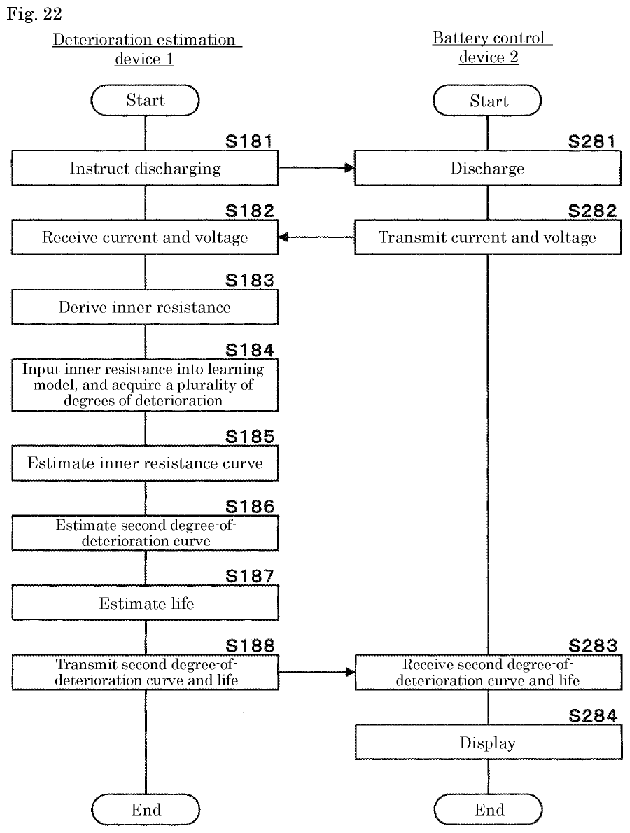

FIG. 22 is a flowchart illustrating steps of processing in which a control unit 11 estimates the transition of an internal resistance of the battery 3, and estimates the transition of the degree of deterioration and a life of the battery 3.

The control unit 11 transmits an instruction to the control unit 21 so that the control unit 21 performs discharging until the batteries 3 reach a predetermined estimated SOC (S181).

The control unit 21 performs discharging until the batteries 3 reach the predetermined estimated SOC (S281).

The control unit 21 acquires a current and a voltage from the history data 24, and transmits the acquired current and voltage to the deterioration estimation device 1 (S282).

The control unit 11 receives the current and the voltage (S182).

The control unit 11 derives the internal resistances (S183).

The control unit 11 inputs the internal resistances to the learning model 149 and acquires a plurality of future internal resistances (S184).

The control unit 11 estimates a time-series transition of the internal resistance (internal resistance curve), and stores the estimated transition of the internal resistance in the relationship DB 144 (S185). The control unit 11 derives an internal resistance curve using a method such as linear approximation or curve approximation based on the internal resistance derived this time and a plurality of internal resistances derived in the past. The past internal resistance curves may be stored in the relationship DB 144 based on the data of the deterioration history DB 142, and the internal resistance curve in the current estimation may be derived with reference to the past internal resistance curves.

The control unit 11 estimates the second degree-of-deterioration curve based on the estimated internal resistance curve, and stores the estimated second degree-of-deterioration curve in the use history DB 143 (S186). The control unit 11 estimates the second degree-of-deterioration curve based on the internal resistance curve estimated this time and the first degree-of-deterioration curve (the relationship between the degree of deterioration and the internal resistance) stored in the relationship DB 144.

The control unit 11 acquires the time tₐ when the rate of deterioration becomes a threshold a as the life (exchange time) (S187).

The control unit 11 transmits the second degree-of-deterioration curve and the life to the battery control device 2 (S188), and finishes the processing.

The control unit 21 receives the second degree-of-deterioration curve and the life (S283), displays the second degree-of-deterioration curve and the life on the display panel 25 (S284), and finishes the processing.

According to the present embodiment, the time-series transition of the degree of deterioration or the life of the battery in future can be easily and accurately estimated based on the internal resistance.

The present invention is not limited to the contents of the above-described embodiments, and various modifications can be made within the scope defined by the claims. That is, embodiments acquired by combining technical means that are appropriately modified within the scope defined by the claims are also included in the technical scope of the present invention.

### DESCRIPTION OF REFERENCE SIGNS

1: deterioration estimation device
2: battery control device
3: battery
4: battery module
7: temperature sensor
8: current sensor
10: deterioration estimation system
11: control unit (discharge control unit, first estimation unit, second estimation unit, load adjustment unit, and charge control unit)
12: main storage unit
13, 28: communication unit
14: auxiliary storage unit
141, 23: program
142: deterioration history DB
143: use history DB
144: relationship DB
145: learning model DB
146, 147, 148, 149, 150: learning model
20: power storage system
29: operation unit

1. A deterioration estimation device comprising:
a discharge control unit configured to discharge a lead-acid battery or a lead-acid battery module that includes a plurality of lead-acid batteries until the lead-acid battery or the lead-acid battery module reaches a predetermined SOC; and
a first estimation unit configured to estimate a rate of deterioration of the lead-acid battery or the lead-acid battery module based on internal resistance or conductance derived when the lead-acid battery or the lead-acid battery module is discharged.

2. The deterioration estimation device according to claim 1, wherein the internal resistance is at least one selected from a group consisting of:
a first internal resistance derived based on a current and a voltage immediately before an end of discharging and a current and a voltage immediately after the end of the discharging, and
a second internal resistance derived based on a current and a voltage immediately before a start of charging and a current and a voltage immediately after the start of the charging; and
a third internal resistance derived from a response when an alternating current or an alternating voltage is applied to the lead-acid battery having reached a predetermined SOC.

3. The deterioration estimation device according to claim 1, wherein the first estimation unit is configured to, in a case where an internal resistance or a conductance is inputted to the deterioration estimation device, input the derived internal resistance or conductance to a learning model that outputs a rate of deterioration so as to estimate a rate of deterioration of the lead-acid battery or the lead-acid battery module.

4. The deterioration estimation device according to claim 1, wherein, the first estimation unit is configured to, in a case where a current or a voltage when discharging is performed until the lead-acid battery or the lead-acid battery module reaches a predetermined SOC is inputted to the deterioration estimation device, input an acquired current or voltage to a learning model that outputs a rate of deterioration so as to estimate a rate of deterioration of the lead-acid battery or the lead-acid battery module.

5. The deterioration estimation device according to claim 1, further comprising a second estimation unit configured to estimate a time series transition of a future rate of deterioration or a life based on a time series transition of the derived internal resistance or conductance or a time series transition of the estimated rate of deterioration.

6. The deterioration estimation device according to claim 5, wherein the second estimation unit is configured to, when the internal resistance or conductance or the rate of deterioration is inputted to the deterioration estimation device in time series, estimate time series transition of the future rate of deterioration or life of the lead-acid battery or the lead-acid battery module by inputting the derived internal resistance or conductance or the estimated rate of deterioration to a recurrent neural network that outputs time series transition of the future rate of deterioration or life.

7. The deterioration estimation device according to claim 1, further comprising a load adjustment unit configured to adjust a load of the lead-acid battery or the lead-acid battery module corresponding to the rate of deterioration estimated by the first estimation unit.

8. A deterioration estimation system comprising:
the deterioration estimation device according to claim 1; and
a terminal configured to transmit a current, a voltage, the internal resistance or the conductance to the deterioration estimation device,
wherein the deterioration estimation device is configured to transmit the rate of deterioration estimated by the first estimation unit to the terminal.

9. The deterioration estimation system according to claim 8, wherein the deterioration estimation device includes a charge control unit configured to perform refresh charging of other lead-acid batteries or other lead-acid battery modules using power when the power is discharged by the discharge control unit.

10. A deterioration estimation method comprising the steps of:
deriving an internal resistance or conductance in a case where a lead-acid battery or a lead-acid battery module that includes a plurality of lead-acid batteries is discharged until the lead-acid battery or the lead-acid battery module reaches a predetermined SOC; and
estimating a rate of deterioration of the lead-acid battery or the lead-acid battery module based on the derived internal resistance or conductance.

11. A computer program that allows a computer to execute processing that includes: deriving an internal resistance or conductance in a case where a lead-acid battery or a lead-acid battery module that includes a plurality of lead-acid batteries is discharged until the lead-acid battery or the lead-acid battery module reaches a predetermined SOC; and
estimating a rate of deterioration of the lead-acid battery or the lead-acid battery module based on the derived internal resistance or conductance.
